(19) United States
(12) Patent Application Publication
(10) Pub. No.: US 2017/0016943 A1
(43) Pub. Date: Jan. 19, 2017

(54) Temperature Profiling in an Electricity Meter

(71) Applicant: Landis+Gyr, Inc., Lafayette, IN (US)

(72) Inventors: Warren Thomas Martin, Lafayette, IN (US); John T. Voisine, Lafayette, IN (US)

(21) Appl. No.: 15/277,999

(22) Filed: Sep. 27, 2016

Related U.S. Application Data
(62) Division of application No. 12/537,920, filed on Aug. 7, 2009.
(60) Provisional application No. 61/188,228, filed on Aug. 7, 2008.
(60) Provisional application No. 61/188,247, filed on Aug. 7, 2008.

(51) Int. Cl. G01R 22/06; G01R 31/28; G01K 1/14; G01R 22/10

(52) U.S. Cl. CPC G01R 22/068; G01R 22/10; G01R 31/2849; G01K 1/14

(57) ABSTRACT

An arrangement includes a plurality of electricity meters and a control station. Each of the plurality of electricity meter includes a memory storing temperature information regarding the electricity meter, and a communication device. The control station is configured to receive temperature information from each of the plurality of electricity meters, for example, by way of the communication device of the electricity meters. The control station is also configured to process the temperature information from the plurality of electricity meters to generate at least one diagnostic value.

This application is a divisional application of U.S. patent application Ser. No. 12/537,920, filed Aug. 7, 2009, which claims the benefit of U.S. Provisional Patent Application Ser. No. 61/188,228, filed Aug. 7, 2008, and U.S. Provisional Patent Application Ser. No. 61/188,247, filed Aug. 7, 2008, both of which are incorporated herein by reference.

### FIELD OF THE INVENTION

This invention relates generally to electricity meters, and more particularly, electricity meters having a processing circuit.

### BACKGROUND OF THE INVENTION

Electricity meters are devices that measure and/or meter aspects of energy provided to a load. The load may be a residence, business, or even part of a larger electricity distribution system. Commonly available meters include electromechanical meters and electronic meters.

Electromechanical meters employ a rotating disk that rotates in response to electric and magnetic fields induced by the electricity passing to the load. As is known in the art, the disk rotation speed is a function of the amount of electricity delivered to the load. Mechanical counters accumulate the number of disk rotations, which is indicative of energy consumed by the load. In some cases, an electromechanical meter can employ processing circuitry to perform additional operations with the consumption information provided by the rotating disk.

Electronic meters typically employ processing circuitry instead of the rotating disk and mechanical counters. In such meters, sensors within the meter detect the voltage and current that is delivered to the load. Circuitry within the meter converts the sensed voltage and current into digital values. Processing circuitry then employs digital signal processing to calculate consumed energy, among other things, from the digital values. Electronic meters provide greater flexibility in the types of energy consumption information that they may calculate, track, and store.

Regardless of the style of meter, electricity meters are typically installed in or near the exterior of a building. As a result, electricity meters are often subjected to a wide range of environmental and electrical conditions, and are thus designed to withstand extremes in weather, as well as some degree of voltage and current swings.

However, there are conditions that can degrade the condition of a meter, or contribute to the failure of a meter. When a meter fails, considerable expense is incurred to repair and/or replace the meter. Furthermore, meter failure can result in loss of electrical service to the load, or at least in the loss of revenue due to the energy supplier due to the inability to measure consumption.

There is always a need to reduce the number of meter failures, or at least the cost associated with meter failures.

### SUMMARY

At least some embodiments of the present invention address the above described need, as well as others, by profiling the internal temperature of the meter, and/or using information regarding a recorded temperature profile of one or more meters for predictive diagnostics and/or maintenance. Such information may be used to help predict the failure of components, or at least identify conditions of the meter that could potentially contribute to failure. Such conditions may be addressed, thereby reducing the number of failures. In meters that employ processing circuits, all or some of the storing and/or processing of temperature data may be carried out by the existing processing circuitry.

In some embodiments, the invention involves logging temperature measurements for various time periods over a length of time. This log of temperature measurements provides a profile of the internal temperature of the meter over time. If the temperature profile deviates significantly from an expected pattern, then it may be a predictor of a pending fault in the meter. In some embodiments, the temperature profile for each month (or some other finite amount of time) is uploaded to a central facility. The central facility performs analysis on the data to determine if the temperature profile indicates a possible or potential degradation or malfunction.

Accordingly, different embodiments of the invention involve using a meter's internal temperature as a means of determining meter performance data, such as estimated reliability or product life, circuit malfunctions that cause overheating, and conditions of excessive heating of a meter's current coils due to a loose socket jaw. Profiling the “under the cover” temperature can also be used to compensate for factors that are influenced by temperature such as registration accuracy, or clock accuracy, etc.

In a first embodiment, an arrangement for use in a utility meter includes a temperature sensor, a memory device, a communication circuit and a processing circuit. The processing circuit is operably coupled to receive information representative of temperature measurements from the temperature sensor, and is configured to store first temperature information associated with a first time period in a first data record in the memory device. The first temperature information is preferably a representation of one or more of the temperature measurements. The processing circuit is further operable to store subsequent temperature information associated with corresponding subsequent time periods in corresponding other data records in the memory device. The processing circuit is also configured to periodically cause the communication circuit to communicate information representative of the first temperature information and the subsequent temperature information to an external device.

In a second embodiment, an arrangement includes a plurality of electricity meters and a control station. Each electricity meter includes a memory storing temperature information regarding the electricity meter, and a communication device. The control station is configured to receive temperature information from the plurality of electricity meters. The control station is further configured to process the temperature information from the plurality of electricity meters to generate at least one diagnostic value.

The above described features and advantages, as well as others, will become more readily apparent to those of ordinary skill in the art by reference to the following detailed description and accompanying drawings.

### BRIEF DESCRIPTION OF THE DRAWINGS

FIG. 1 shows a schematic diagram of an exemplary meter that includes an arrangement for temperature profiling in accordance with an embodiment of the invention;

FIG. 2 shows a flow diagram of an exemplary set of operations performed within the meter of FIG. 1 to record temperature information;

FIG. 3 shows a flow diagram of an exemplary set of operations performed within the meter of FIG. 1 to transfer temperature information to an external device.

FIG. 4 shows a schematic block diagram of an arrangement for collecting and using temperature data from a plurality of electricity meters;

FIG. 5 shows a flow diagram of an exemplary set of operations performed by the control station of FIG. 4; and

FIG. 6 shows a schematic diagram of an exemplary meter that includes an arrangement for temperature profiling in accordance with another embodiment of the invention.

### DETAILED DESCRIPTION

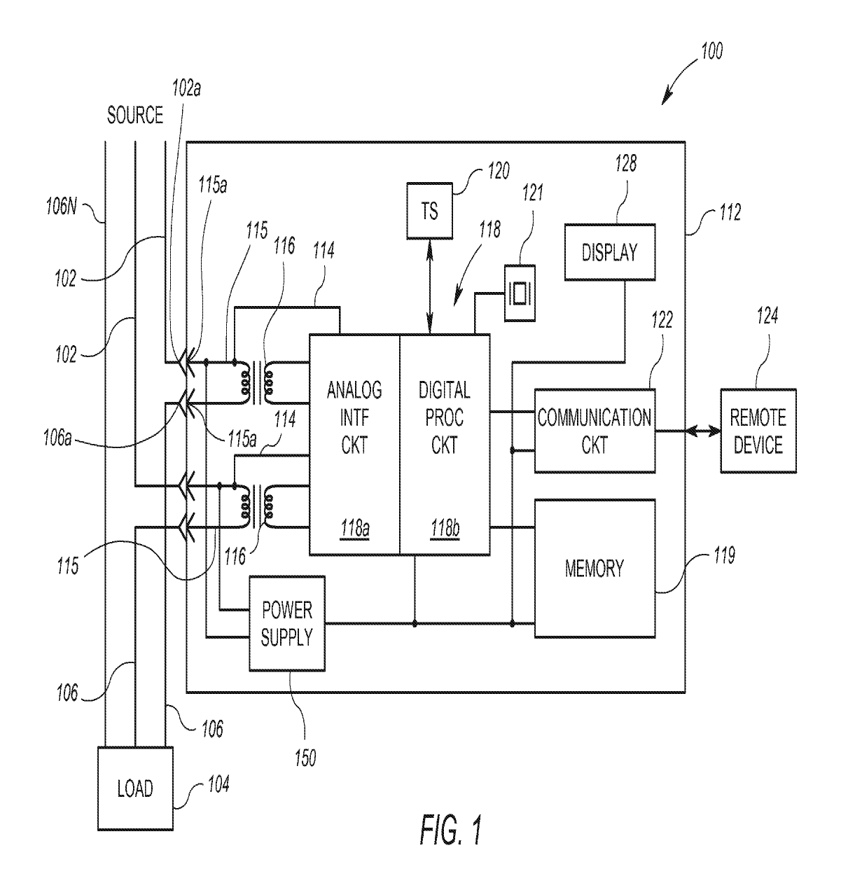

Referring now to the drawings, and more particularly to FIG. 1, a diagram of an exemplary electrical utility meter 100 constructed according to a first embodiment of the present invention is shown. As shown in FIG. 1, the meter 100 includes a housing 112 in which are disposed first and second current coils 115, first and second current measurement devices 116, voltage measurement devices 114, a processing circuit 118, a memory 119, a temperature sensor 120, a crystal oscillator circuit 121, a communication circuit 122, a display 128, and a power supply 150.

In FIG. 1, the meter 100 is operably coupled to two utility power lines 102 via first ends of each of the first and second current coils 115. The utility power lines 102 are connected to a source of electricity, such as a utility power transmission and distribution system, not shown. A load 104 (typically a consumer of electrical power) is connected to the power lines 102 through two feeder lines 106. The meter 100 is operably coupled to the feeder lines 106 via second ends of each of the first and second current coils 115. An additional utility power line 106n is the “neutral” line that extends between the source and the load 104.

Because the first and second current coils 115 are connected in the path between the power lines 102 and the feeder lines 106, the first and second current coils 115 provide access, within the meter 100, to the electricity delivered to the load 104. As will be discussed, other circuitry within the meter 100 is operably connected to the current coils 115 to detect the delivered electricity and, among other things, generate metering information representative of a quantity of electrical energy delivered to the load 104.

A housing 112 is disposed over the meter 100 and encases the various components thereof. The housing 112 may take any suitable form, and is generally configured to withstand a wide range of environmental conditions. The housing 112 thereby provides at least some protection against environmental conditions to the various elements disposed therein. Meter housings are well known in the art. The power supply 150 is a power supply circuit that provides bias power for the various circuits within the meter 100. The power supply derives the power from the AC power provided across the power lines 102 as is known in the art.

In this embodiment, the temperature sensor 120 is a sensor element and associated circuitry that is disposed “under the glass” or within the housing 112 in order to detect temperatures within the interior of the meter 100. In this embodiment, the sensor 120 is preferably placed in a location that will not be unduly influenced by a particular heat-generating element within the meter 100, such as the power supply 150 or the processing circuit 118. In other embodiments, the sensor 120 may be placed on the exterior of the meter 100 if desired. In still other embodiments, multiple sensors are used, with sensors specifically located near the different heat-generating elements so that the temperature behavior of such elements (e.g. the power supply 150, the processing circuit 118 and/or the current coils 115 or current blades 115a) may be monitored and analyzed. Further details regarding such an embodiment are described below in connection with FIG. 6.

In any event, the temperature sensor 120 may suitably include a sensing device that generates a signal that is dependent upon the ambient temperature. It is known to use the temperature-dependent electrical behavior of diodes as means to obtain a voltage signal representative of temperature. Other suitably small temperature sensors are known. The temperature sensor 120 can be an integral part of an integrated circuit, such as the processing circuit 118, located on a circuit board not shown, or a separate device located on the circuit board or elsewhere inside the meter. This circuit board may suitably be the circuit board that includes the power supply 150 and/or the processing circuit 118.

In any event, the processing circuit 118 is operably connected to the temperature sensor 120 to generate a digital temperature measurement value therefrom.

As discussed above, the current coils 115 are conductors that pass the current from the power lines 102 to the feeder lines 106. The current coils 115 extend at least through the interior of the housing 112 to provide access to measurements of current and voltage delivered to the load 104 within the meter 100. The current coils 115 typically end in blades (exemplified by blades 115a) that connect to sockets, i.e. jaws, (e.g. sockets 102a, 106a) that form respective terminations of the power lines 102 and feeder lines 106 at the meter 100. Various configurations of current coils, sockets and meter blades are known in the art.

Voltage sensors 114 and current sensors 116 are secured within the housing 112. In general, the sensors 114, 116 are operably coupled to the current coils 115 to detect, respectively, voltage and current signals representative of voltage and current provided to the load 104, and to generate measurement signals therefrom. In particular, each of the voltage sensors 114 is configured to generate an analog voltage measurement signal having a waveform representative of the voltage provided to the load 104. Similarly, the each of the current sensors 116 is configured to generate an analog current measurement signal having a waveform representative of the current provided to the load 104. For purposes of example and explanation, FIG. 1 illustrates two voltage sensors 114 and current sensors 116 for generating measurement signals for two sides of a 240-volt single-phase three-wire electrical service. However, it will be intuitive to those skilled in the art that the principles of the present invention may also be applied to three-phase power systems.

In this embodiment, the voltage sensors 114 are configured to obtain a voltage measurement by direct contact with the current coil 115. The voltage sensor 114 (or the analog interface circuit 118a, discussed below) may include a voltage divider circuit to bring the measured voltage waveform to a magnitude that is suitable for a standard A/D converter. The voltage sensors 114 may alternatively take other known forms. Also in this embodiment, the current sensors 116 comprise toroid current transformers, which are inductively coupled to the current coils 115. Such devices for current measurement are well known.

The processing circuit 118 is operable to receive the analog measurement signals from the voltage sensors 114 and the current sensors 116 and generate energy consumption data therefrom. According to an exemplary embodiment, the processing circuit 118 includes analog interface circuitry 118a that receives and digitizes the measurement signals (and thus typically contains an A/D converter), and digital processing circuitry 118b that processes the digitized measurement signals to thereby generate the energy consumption data. Such circuits are well known in the art.

In one embodiment, the digital measurement signals consist of sampled voltage measurement waveforms and sampled current waveforms. To obtain such digital measurement signals, the analog interface circuit 118a samples the voltage measurement signals received from two voltage sensors 114 to generate two respective digital voltage signals VSA and VSB, and also samples the current measurement signals received from the current transformers 116 to generate two respective digital current signals ISA and ISB. Each of the signals VSA and VSB consists of a series of samples that is representative of the voltage waveform on one of the two power lines 102, after being scaled. Each of the signals ISA and ISB consists of a series of samples that is representative of the current waveform on one of the two power lines 102.

In some embodiments, the analog interface circuit 118a samples the voltage measurement signals received from two voltage sensors 114 to generate a single digital voltage signal VSAB which is representative of the voltage differential between the two power lines 102. In such embodiments, the individual power line digital waveforms VSA and VSB may be determined using ½ VSAB.

The use of digital current and voltage signals such as VSA, VSB, ISA and ISB to generate various metering information is well known in the art. By way of example, the digital processing circuitry 118b may, for electrical line phase, multiple contemporaneous current samples and voltage samples (e.g. VSA(n)*ISA(n) and VSB(n)*ISB(n)), and sum the resulting products, to generate a value representative of energy consumption (watt-hours). Such methods and variants thereof are well known. In other examples, the digital processing circuit 118b may generate RMS current and voltage values by averaging squares of the respective current and voltage values.

Moreover, the use of digital sampling of measured current and voltage allows for various additional measurements.

As is known in the art, the processing circuit 118 may include one or more integrated circuits, and may include a microcontroller, microprocessor, digital signal processor, or any combination thereof. One common architecture of the digital processing circuitry 118b used in electricity meters includes a digital signal processor and another microprocessor or microcontroller.

In addition to the above described operations relating to performing metering calculations, the processing circuit 118 also forms part of an arrangement for sensing, recording and communicating temperature-related information regarding the meter 100. It will be appreciated, however, that the processing operations relating to temperature sensing, recording and communicating may alternatively be performed in full, or in part, by a processing device that is not also responsible for metering calculations.

In this embodiment, however, the processing circuit 118 performs metering calculations as well as temperature logging or profiling. To this end, the processing circuit 118 is also operably coupled to receive information representative of temperature measurements from the temperature sensor 120. The processing circuit is also configured to store first temperature information associated with a first time period in a first data record in the memory 119, the first temperature information derived from one or more of the temperature measurements. Thereafter, the processing circuit stores similar temperature information associated with corresponding subsequent time periods in corresponding other data records in the memory 119.

In further detail, the processing circuit 118 preferably stores a temperature measurement for each interval of a predetermined time period, for example, fifteen, thirty or sixty minutes. The processing circuit 118 also stores date and time information in the memory 119 such that each data record can be associated with a specific real time interval.

In addition to storing temperature information, the processing circuit 118 is configured to periodically cause the communication circuit 122 to communicate information representative of the first temperature information and the subsequent temperature information to an external device. In one embodiment, for example, the processing circuit 118 causes all of the temperature measurements in the data records in the memory 119 to be communicated to an external device so that the memory 119 may be purged and re-used.

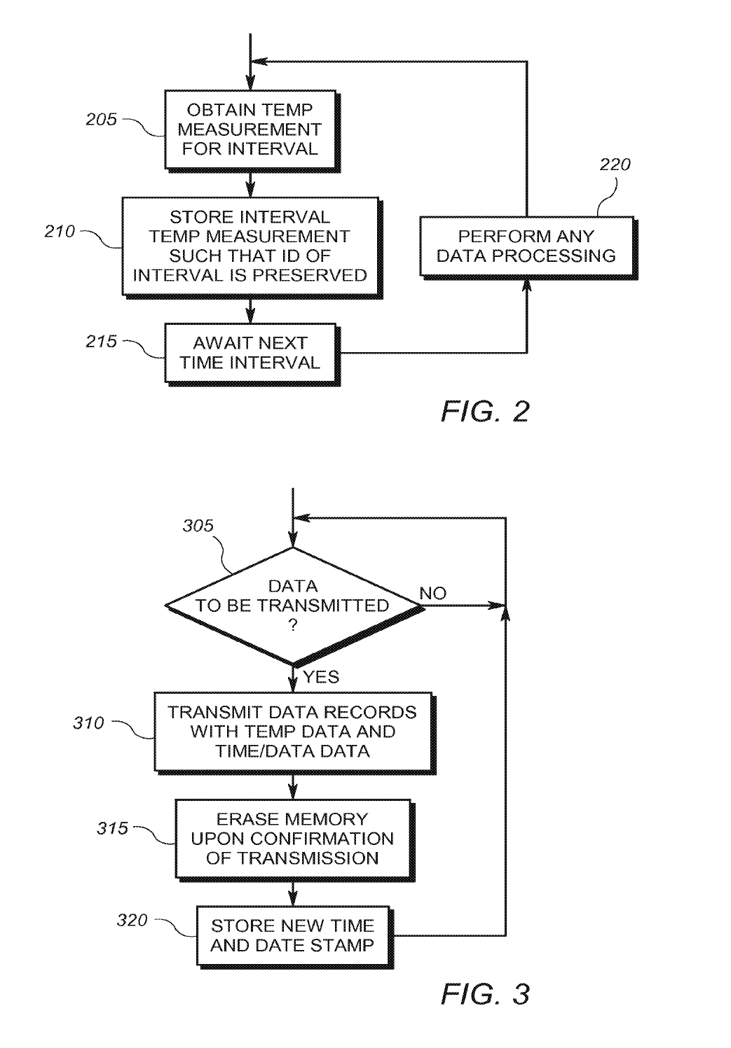

Further detail regarding the operation of the processing circuit 118 in the temperature data logging operation is provided below in connection with the description of FIG. 2.

Referring again specifically to FIG. 1, the memory 119 includes one or more storage devices of different types. The memory 119 may include volatile or non-volatile RAM, EEPROM, or other readable and writeable memory devices. In this embodiment, the memory 119 is a non-volatile memory that stores a data log containing a plurality of temperature information data records, each data record including temperature information corresponding to a different time period. The data log of temperature information for various time periods is stored such that the time period corresponding to each data record may be ascertained. For example, the memory 119 may store a time and date stamp and a sequence of data records. If the time period interval is known, and each data record can be sequentially related to the time and date stamp, then the time interval between the time and date stamp and each data record can be ascertained. Other methods of associating a date and time with each temperature information data record may be used, such as individual time stamps stored with each record.

The communication circuit 122 is one or more devices, and supporting circuitry, that is operably coupled to the processing circuit 118, and is configured to communicate with a remote device 124. The communication circuit 122 may, for example, transmit signals to the remote device 124 via a tangible communication link (e.g., cable, wire, fiber, etc.), or via a wireless communication link. As discussed above, the communication circuit 122 is operable to transmit data representative of the temperature information data log stored in the memory 119 to an external device. Such information may be used for later diagnostics of a meter malfunction, or in routine diagnostics to determine the possible onset of an adverse condition of the meter 100.

The display 128 is operably coupled to the processing unit 118 and provides a visual display of information, such as information regarding the operation of the meter 100. For example, the display 128 may provide a visual display regarding the energy consumption measurement (or even temperature profiling or measurement) of the meter 100.

The meter 100 performs well-known operations to obtain and record energy consumption information using the sensors 114, 116 and the processing circuit 118. In addition, the meter 100 measures temperature, preferably inside the meter housing 112, and records temperature in the memory 119.

To this end, FIGS. 2 and 3 show exemplary flow diagrams of operations that may be performed by the processing circuit 118 in connection with temperature recording operations. FIG. 2 shows a set of operations for a software process that records and/or processes temperature data in accordance with one embodiment of the invention. FIG. 3 shows a set of operations for a software process that periodically uploads or transfers temperature profile data to an external device, such as a portable computing device or a remote central data facility.

Referring to FIG. 2, in step 205, the processing circuit 118 obtains information representative of a temperature measurement within the meter 100. As discussed above the processing circuit 118 is operably connected to the temperature sensor 120 for this purpose. As is known in the art, the temperature sensor 120 includes, or is connected to, circuitry that converts the temperature measurement into a format usable by the processing circuit 118. To this end, the sensor information may be converted to a digital value, or provided a special analog input of the processing circuit 118 as an analog voltage representative of temperature.

In this embodiment, the temperature information represents the temperature information for a current block of time. More specifically, the temperature profile constitutes temperature information for a plurality of blocks of time, preferably sequential. In a common example, each block of time, or profile period, has the same duration. The duration may be defined by a user via an input to the communication circuit 122. Profile periods of 15 minutes, 30 minutes, and an hour in length are suitable, although in theory any time duration is possible. The duration of the profile periods, however, should be chosen to balance the need for data granularity with the need to avoid collecting unnecessarily large amounts of data.

In any event, in step 205, the temperature information for the current profile period is obtained. In this embodiment, one measurement is used for the entire profile period. In other embodiments, the processing circuit 118 may obtain multiple measurements over each profile period and then determine the temperature information for the profile period by averaging, or taking the median of, the multiple measurements.

After obtaining the temperature information in step 205, the processing circuit 118 performs the operations of step 210. In step 210, the processing circuit 118 stores the internal temperature measurement in the memory 119. As discussed above, the temperature measurement is stored as a data record in a manner that associates the temperature information with the contemporaneous date and time. For example, the memory 119 may store temperature information for the profile periods as a sequence of data records. The record sequence may be stored in a physically sequential manner, or in a logically sequential manner. In any event, the position of each data block within the sequence of blocks indicates its position. Each sequence may include a time and date stamp.

Consider an example wherein each profile period is a 30 minute period, and wherein a sequence has an initial date and time stamp of 01-01-2008 08:00. A sequence of data records storing temperature values of 23, 24, 24, 24, 25, 23 would represent the temperature profile illustrated in Table I.

TABLE I

| Date | Time | Temp. |
|---|---|---|
| Jan. 1, 2008 | 08:00-08:30 | 23 |
| Jan. 1, 2008 | 08:30-09:00 | 24 |
| Jan. 1, 2008 | 09:00-09:30 | 24 |
| Jan. 1, 2008 | 09:30-10:00 | 24 |
| Jan. 1, 2008 | 10:00-10:30 | 25 |
| Jan. 1, 2008 | 10:30-11:00 | 23 |

It will be appreciated that the manner of storing temperature information for profile periods such that they associated with a specific time and date may suitably be the same as known methods for storing load profiling information.

After step 210, the temperature information for the current profile period is stored in the memory 119. The processing circuit 118 then awaits for the completion of the next time interval or profile period in step 215. Thus, in the above, example, the processing circuit 118 would wait until the next 30 minute period has passed. To make this determination, the processing circuit 118 maintains a real-time clock, as is known in the art. In the embodiment of FIG. 1, the real-time clock maintained in the processing circuit 118 may be based on the oscillator circuit 121, the line frequency of the power lines 102, or a combination of both. Regardless, after the next profile period has completed, the processing circuit 118 returns to step 205.

During the profile period, the processing circuit 118 may periodically perform data processing using the temperature information, as illustrated by step 220. For example, the processing circuit 118 may analyze the temperature data to determine if the current temperature indicates a possible malfunction, or if the temperature trend over several time periods indicates a potential malfunction.

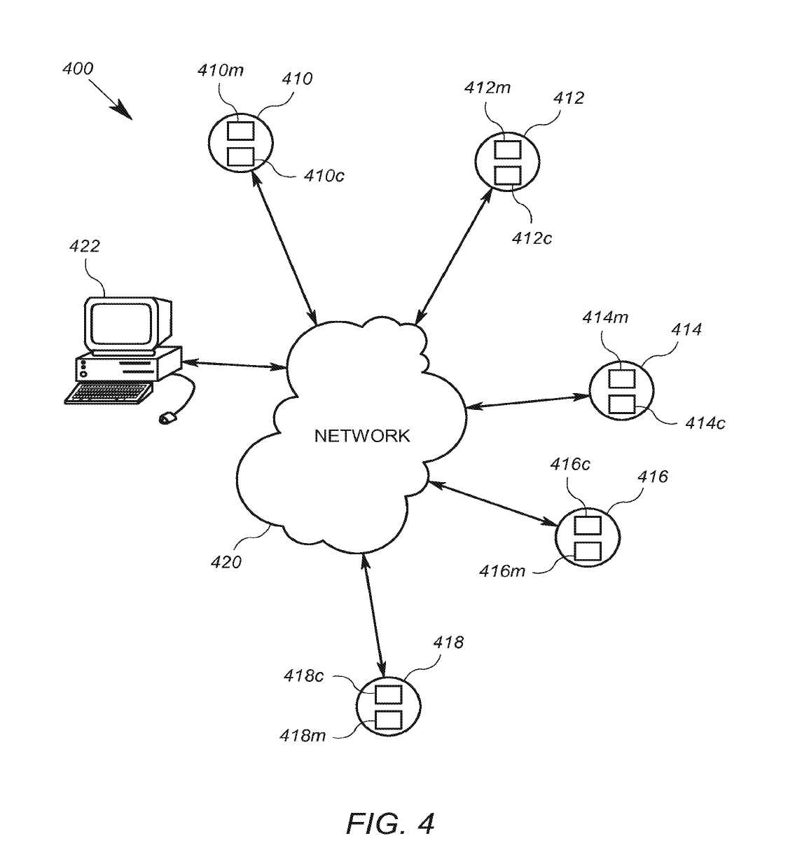

In many embodiments, much of the analysis of the temperature data takes place in a separate processing device, such as the control station 422 of FIG. 4, discussed further below. FIG. 3 shows a set of operations carried out by the processing circuit 118 to transfer the temperature data records (or temperature profile data) to an external device, such as the external device 124. Periodically, such as once per day, week or month, the processing circuit 118 causes the communication circuit 122 of the meter 100 to transfer the temperature data from the memory 118 to an external device. The external device may be a locally connected data gathering device (i.e. a portable computer or handheld unit), or may be centralized data processing device. Accordingly, the communication circuit 122 may include optical communication devices for local communications, and/or a wireless modem or power line modem for remote communications.

In step 305, the processing circuit 118 determines whether temperature profile data is to be transmitted. In particular, temperature profile data transfer may be triggered as a scheduled event initiated within the processing circuit 118 itself. Alternatively, temperature profile data transfer can be triggered by a query signal or command signal received from the external device via the communication circuit 122. Regardless of how initiated, the processing circuit 118 only proceeds to step 310 when it is time to transfer the temperature profile data. In general, temperature profile data may suitably be transferred daily, weekly or monthly.

In step 310, the processing circuit 118 causes the temperature profile data to be transferred from the memory 119 to the external device via the communication circuit 122. The processing circuit 118 also transfers any date and time information corresponding to the temperature profile data to the external device.

Upon successful completion of the transfer of the temperature profile data, the processing circuit 118 in step 315 causes temperature profile data to be erased from the memory 119. Thereafter, in step 320, the processing circuit 118 stores a new time and date stamp in the memory 119 which will be used as the time and date stamp for the new set of temperature profile data. The processing circuit 118 thereafter accumulates data in accordance with the operations of FIG. 2 until it is time to transmit data again as per step 305 of FIG. 3.

At least one aspect of some embodiments of the invention involves the use of temperature profile data from multiple meters to perform data analysis regarding reliability and potential malfunction detection or prediction. FIG. 4 shows an exemplary architecture that supports this aspect. In particular, FIG. 4 shows an arrangement 400 that may be employed by an electric utility to obtain and utilize temperature information from a plurality of meters.

The arrangement 400 includes a plurality of electricity meters 410, 412, 414, 416 and 418, a network 420, and a control station 422. Each electricity meter 412, 414, 416 and 418 includes a memory 410m, 412m, 414m, 416m and 418m that stores temperature information regarding the electricity meter, and a respective communication device 410c, 412c, 414c, 416c and 418c. By way of example, each electricity meter 410, 412, 414, 416 and 418 may be structured similar to the meter 100 of FIG. 1.

The control station 422 is a computer system that is configured to receive the temperature information from the plurality of electricity meters 410, 412, 414, 416 and 418. The control station 422 is further configured to process the temperature information from the plurality of electricity meters to generate at least one diagnostic value. The diagnostic value may, for example, include information identifying whether one or more of the plurality of electricity meters should be scheduled for service. For example, if the temperature profile for the meter 412 is vastly different (i.e. showing higher temperatures) than the meters 410, 414, 416 and 418, and if historically the meter 412 has had a temperature profile similar to those of the meters 410, 414, 416 and 418, then it is an indication that the meter 412 may have an issue requirement repair or maintenance.

The diagnostic value may also include a value representative of a predicted meter failure rate. A predicted failure rate of meters may be used by the utility to and meter manufacturer in planning, negotiating warranty terms and maintenance planning. Further detail regarding this operation is described further below.

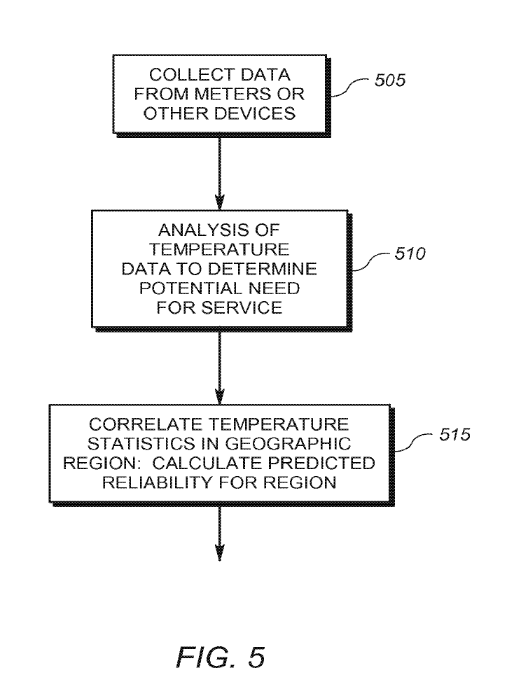

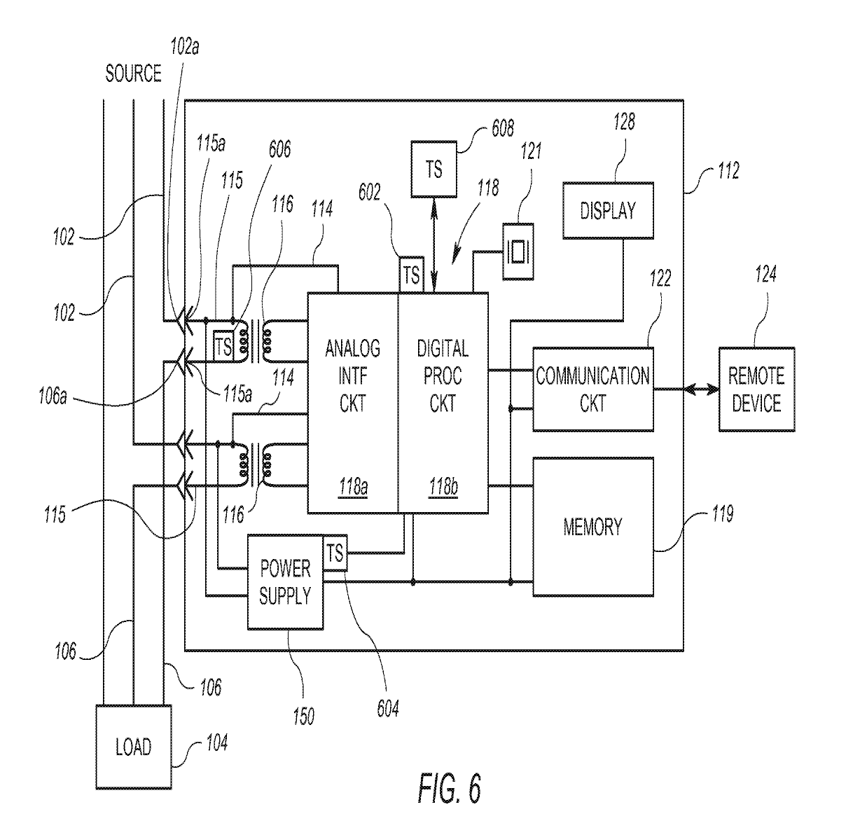

FIG. 5 shows an exemplary set of operations that may be performed by the control station 422 of FIG. 4 to gather and analyze meter temperature data. In step 505, the control station 422 obtains temperature information from the plurality of meters 410, 412, 414, 416 and 418. In the embodiment described herein, the control station 422 may be operably connected to a network 420 that facilitates communication with the communication circuits 410c, 412c, 414c, 416c and 418c. By way of example, the network 420 can be a pager radio network, and the communication circuits 410c, 412c, 414c, 416c and 418c may include pager radio modems. In another example, the network 420 can be a power line communication network that utilizes the electrical power lines for data communication. Such systems are known. In another example not illustrated, a technician may bring a portable computer, not shown, to each of the meters 410, 412, 414, 416 and 418 and obtain the temperature data directly from the meters. In such a case, the communication circuits 410c, 412c, 414c, 416c and 418c may include optical transmission and reception circuitry, or Bluetooth wireless communication capability.

In this embodiment, the temperature information received from the meters 410, 412, 414, 416 and 418 is temperature profile data. The temperature profile data, as discussed further above, includes representative temperature information for each of a plurality of time intervals (i.e. profile periods) for each of the meters 410, 412, 414, 416 and 418. Such information may suitably be stored in the memories 410m, 412m, 414m, 416m and 418m using the process discussed above in connection with FIG. 2.

It will be appreciated, however, that in other embodiments, the temperature information transmitted by the meters may consist of values derived from the temperature information, such as statistical values, values representative of alarm conditions detected by the meters, etc.

Referring again to this embodiment, the result of step 505 is that the control station obtains information representative of the temperature profile for each of the meters 410, 412, 414, 416 and 418. For example, the control station 422 may receive the temperature values for every 30 minute interval for each meter 410, 412, 414, 416 and 418 over a one-month time period.

In step 510, the control station 422 performs analysis of the temperature data to determine the potential need for service. To this end, the control station 422 may compare the temperature profiles of the meters 410, 412, 414, 416 and 418 and attempt to detect abnormalities in one or more of the meters. Temperature information may be filtered such that ordinary temperature variances among the meters 410, 412, 414, 416 and 418 are taken into account. Such temperature variances may relate to location and/or orientation of the meter, etc.

If the control station determines that temperatures for a particular meter, e.g. meter 412, are “out of normal”, then there are a number of possible causes. For example, the out of normal temperature profile may be an indication of an overheating circuit due to a circuit failure or an impending circuit failure. Alternatively, the detected excessive heat may be an indication of an external heat source increasing the temperature of the meter 412. In another alternative, the detected excessive heat may be an indication of a loose connection between the meter blade and the socket or jaw. In particular, a loose connection between the meter blade and socket jaw can cause overheating to such a degree that plastic surrounding the blade can begin to deform.

Accordingly, the control station 422 may perform analysis of the data in a manner that can identify conditions consistent with these potential problems. For example, if periods of abnormally increased temperature accompany periods of increased power usage, then the control station 422 may indicate the possibility of a deteriorating connection of a meter blade and jaw. A poor connection between the meter blade and jaw creates a resistive path, which heats at high load current levels. To carry out this analysis, the control station 422 would also typically require load profile data from the meter 412. Load profile data is known in the art, and consists of energy consumption values over a plurality of time intervals. With such data, the control station 422 can correlate temperature increase to load current. If the abnormally high temperature correlates to high energy usage as indicated by the load profile data, then the control station may indicate via a display the possibility of a poor connection between the meter blade and jaw.

If, instead, the control station 422 does not detect a correlation between energy consumption peaks and abnormally high temperature measurements in the meter 412, then the problem is less likely to be associated with the interconnection of the meter blade and jaw.

In such a case, if the control station 422 detects abnormally high temperatures for a continuous time period, followed by a long-term return to normal temperatures, the control station 422 may provide an indication of a possible external source of heat, such as a nearby fire. The control station 422 may provide a visual indication of the data and an indication that the abnormal temperatures could be from an external source.

If the control station 422 detects a gradual increase to abnormally high temperatures, then the control station 422 may provide an indication that there are general circuitry issues within the meter that potentially require maintenance.

The control station 422 may suitably display such indications of possible issues arising from the temperature analysis on a human-readable display. Such indications may also be provided to users via e-mail or other notification devices. The control station 422 may simply store such information in a manner that may be readily retrieved by software applications that can be used to schedule maintenance and diagnosis of meters.

In addition to detecting specific issues with specific meters, the temperature information may be used to determine useful information regarding the entire field of meters 410, 412, 414, 416 and 418. To this end, in step 515, the control station 422 uses the information to calculate the predicted reliability meters within a region such as the region illustrated in FIG. 4.

In particular, temperature profiling can be used to predict product reliability and subsequent failure rates and then this information can be used to modify warranty programs or maintenance schedules that vary according to geographical regions. For example, meters exposed to higher external temperatures may exhibit higher failure rates than those exposed to lower external temperatures. These facts may be used to form different warranty programs and/or maintenance schedules in different geographical areas.

Currently, failure rates and reliability for devices such as meters are calculated using models. Common reliability models such as the Siemens Norm SN29500-1 are based on the presumption that the meter has an ambient temperature of 40° C. However, if it is assumed that the percent failures per year doubles for every 10° C. increase in temperature an algorithm similar to the following can be employed. The relationship between % failures per year and temperature can be described by the formula:

%/Yr=0.0625Re^{0.693temp}

assuming that the percent failures per year double each time the temperature increases 10° C. The value R represents estimated percentage of failures per year at 40° C., such as determined using the Siemens Norm SN29500-1. A typical value for R could be 0.2. A failure rate of 0.2% per year could be interpreted as a 99.8% probability that any given metering product will remain functional in a year. Thus, if there are one thousand meters in service, then there is a probability that two units will fail in a year's time.

Since temperature varies unpredictably, the control station 422 could use the following formula to estimate “average” percentage of failures per year where N is the number of temperature readings taken, tempn is a particular (nth) temperature reading, and r_{average} represents the average percentage of failures per year of a product.

$${r}_{Average} = \frac{1}{N} {\sum }_{1}^{N} 0.0625 R {e}^{.0693 {temp}_{n}}$$

For example if temperature is measured every 15 minutes there would be 35,040 measurements of temperature taken each year. Hence over a period of one year N=35,040.

The control station 422 may provide an indication of the percentage of failure rate to a user via a display, and/or store or communicate the information. The information may be used by the electric utility for planning, and may be used to help determine appropriate warranties.

It is noted that the control station 422 may perform other operations with the temperature profile data from the meters 410, 412, 414, 416 and 418. Similarly, the control station 422 need not perform the operations listed in FIG. 5.

Another possible use for recording temperature in an electric meter is to improve the accuracy of a real time clock within the meters 410, 412, 414, 416 and 418 in a very inexpensive manner. As discussed further above, many electricity meters maintain a real-time clock, which is used for multiple purposes. Thus, it can be assumed that the meters 410, 412, 414, 416 ad 418 each maintain a real-time clock, not shown. One standard implementation of real-time clock is to base the clock off of a standard watch crystal having a frequency of 32.768 kHz. Such devices have a temperature coefficient of typically 0.04 ppm per change in temperature from 25° C., squared. Then if temperature is measured and the following formula used the effect of temperature variations can be partially compensated for and clock accuracy improved.

$$TimeComp = \frac{1}{N} {\sum }_{1}^{N} 0.04 {( {T}_{n} - 25 )}^{2}$$

where Tₙ=the nth temperature measurement in degrees C., and N is the number of readings obtained. The value “TimeComp” is the amount in ppm that the clock time would be reduced to compensate for temperature from the time temperature readings were started.

Such operations may be carried out by the control station 422. In such a case, the control station 422 would periodically calculate a clock adjustment for each meter 410, 412, 414, 416 or 418 based on the temperature profile data received therefrom. The control station 422 would then communicate the clock adjustment information to each meter 410, 412, 414, 416 or 418. In the alternative, each meter may determine its own adjustment. For example, the processing circuit 118 of the meter 100 of FIG. 1 may be configured to periodically calculate a clock adjustment based on the temperature profile data stored in the memory 119. The processing circuit 118 would then implement the adjustment in its real time clock.

Methods of adjusting of a real-time clock in a meter are known, and will vary based on the implementation of the clock. In one version, the processing circuit 118 counts pulses from the crystal oscillator 121 and registers one second for every N pulses (i.e. every 32,768 pulses). To adjust the real-time clock, the processing circuit 118 merely adjusts the number of crystal oscillator pulses that are accumulated before registering a second.

FIG. 6 shows an alternative embodiment of FIG. 1 wherein multiple temperature sensors 602, 604, 606 and 608 are used. While the use of additional sensors adds expense and complexity, the additional information provided by the sensors can provide more extensive advantages.

By way of example, a sensor 602 may be placed on or next to the processing circuit 118 to provide temperature information therefor. It can be useful to monitor the temperature of the microprocessors and/or other processors that make up the processing circuit. Another sensor 604 may be placed on the power supply 150, for example, on components such as a transformer or a fusing element, not shown. Another sensor 606 may be placed on the current coils 115 located in a meter's base, such as directly adjacent to the blade portion 115a of one or both of the current coils 115. Another sensor 608 may be located in a position not specifically close to any of those elements, or even on the meter cover 112, so that comparative temperatures may be made.

The temperature information from each of the sensors 602, 604, 606 or 608 may be logged in a separate profile to enable analysis of each element. For example, if the overall temperature (i.e. at all sensors 602, 604, 606, 608) of meter 100 rises, but rises most significantly at the sensor 604, then it is an indication that the power supply 150 may be developing a malfunction. Similarly, if the temperature at the sensor 606 rises disproportionately with respect to the other sensors 602, 604 and 608, then it may be an indication of a deteriorating connection between the blade 115a and jaw 102a or 106a, of the meter 100. Such diagnoses may occur at the remote control station 422, or by the processing circuit 118 within the meter, for example, at step 220 of FIG. 2.

Thus, the exemplary embodiment of FIG. 6 requires extra sensors and processing, but can provide more extensive data regarding circuit operation within the meter 100 under different conditions.

It will be appreciated that the above described embodiments are merely illustrative, and that those of ordinary skill in the art will devise their own implementations and modifications that incorporate the principles of the present invention and fall within the spirit and scope thereof.

Temperature measurements can be taken at a specific time of day such as at night time to eliminate any solar heating effects. Temperature thresholds can be programmed to set a flag if exceeded and/or to send a message over the WAN In some embodiments, the temperature log may be stored and accessed locally. In such a case, the communication circuit 122 of FIG. 1 may simply be a communication interface that employs a local communication port to effectuate local communications via an optical port. Such devices are known. In such cases, the temperature information is obtained via a portable computer or device (e.g. device 124) and then analyzed either by the portable computer or at another site. In another embodiment, the temperature log information is stored in the memory 119 and only analyzed upon failure and return of the meter 100 to the factory or repair facility. In such a case, access to the memory 119 in a non-operational meter may be achieved using a removable memory device that can be read by other devices. Such a memory 119 may be part of an expansion board that can be plugged into a slot within the meter 100, or may itself be a memory that is plugged into a corresponding socket 119 within the meter In still another embodiment, the processing circuit 118b performs local analysis of the temperature log, including all or most of that described above in connection with step 510 of FIG. 5. The processing circuit 118b can be programmed to set a flag when the processing circuit 118b determines that the estimated end of life of the meter has been reached. To this end, the processing circuit 118b would calculate estimated end of life using the nominal average end of life of the meter 100, and then adjusting based on temperature variances similar to those discussed above in connection with step 510.

What is claimed is:

1. An arrangement, comprising:
a plurality of electricity meters, each electricity meter including a memory storing temperature information regarding the electricity meter, and a communication device;
a control station configured to receive temperature information from the plurality of electricity meters, the control station further configured to process the temperature information from the plurality of electricity meters to generate at least one diagnostic value.

2. The arrangement of claim 1, wherein the diagnostic value includes information identifying one or more of the plurality of electricity meters to be scheduled for service.

3. The arrangement of claim 1, wherein the diagnostic value includes a value representative of a predicted meter failure rate.

4. The arrangement of claim 1, wherein the control station is further configured to:
evaluate filtered temperature information based on temperature information from each meter for a plurality of time periods;
and determine an adjustment of a metering circuit parameter for at least a first meter, based on the evaluation of the filtered temperature information;
communicate a signal to the first meter, the signal including information representative of the determined adjustment.

5. The arrangement of claim 4, wherein the control station processing circuit is further configured to determine the adjustment such that the adjustment is an adjustment of a metering circuit clock of the first meter.

6. The arrangement of claim 4, wherein the control station processing circuit is further configured to determine the adjustment such that the adjustment is an adjustment of an energy consumption calculation circuit of the first meter.
